(19) United States
(12) Patent Application Publication
(10) Pub. No.: US 2010/0117751 A1
(43) Pub. Date: May 13, 2010

(54) DIGITAL PULSE MODULATORS HAVING FREE RUNNING CLOCK

(76) Inventors: Morten Kragh, Copenhagen N (DK); Ole Neis Nielsen, Copenhagen N (DK)

Correspondence Address: STITES & HARBISON PLLC, 1199 NORTH FAIRFAX STREET, SUITE 900, ALEXANDRIA, VA, 22314, US

(21) Appl. No.: 12/518,921

(22) PCT Filed: Dec. 11, 2007
(86) PCT No.: PCT/IB2007/055023

§ 371 Date: Oct. 26, 2009

(30) Foreign Application Priority Data
Dec. 12, 2006 (DK) PA 2006 01630

(51) Int. Cl. H03K 7/08

(52) U.S. Cl. 332/109

(57) ABSTRACT

The present invention relates to the application of a free-tunning clock signal in a pulse-width modulator (PWM) Specifically there is disclosed an integrated circuit comprising a pulse-width modulator (2) for converting an input signal (6) into a pulse-width-modulated signal (8), the pulse-width modulator (2) being clocked by a clock signal (4) generated by a clock generator (3) which generates a free-running clock signal In a preferred embodiment of the invention, the clock generator (3) is provided in the same integrated circuit (1), such as a chip, as the digital pulse-width modulator (2).

### TECHNICAL FIELD

The present invention relates in general to digital pulse-width modulators (PWM) and the integration of a free-running clock signal, e.g. by using a ring oscillator.

### BACKGROUND OF THE INVENTION

The advantages of power amplification based on a switching power stage are well known. The high efficiency provides several advantages in terms of minimal weight and volume, higher power-handling capability and improved reliability. The fundamental elements in switching power amplification are the modulator and the analogue output stage.

Integrators and multipliers utilised for switching power applications as well as the output of the modulator are driven by a clock. Therefore, the quality of the clock (clock signal) has a direct influence on the result of the modulation in terms of distortion and noise.

Circuits involving digital signal processing are typically clock-driven. In order to prevent data loss, the individual parts of a design are somehow mutually synchronised by a clock several times faster than the sample rate. In prior art it is common to use phase-locked loops (PLL) incorporating voltage-controlled crystal oscillators (VCXO). The principles of PLL operation are covered in many texts. Negative feedback brings the oscillator into lock with the applied timing reference. Below the closed-loop corner frequency, the PLL tracks the reference. Above closed-loop corner frequency, reference jitter is subjected to increasing attenuation, and the PLL jitter performance becomes similar to the oscillator. One problem with such circuits is that VCXO have very narrow frequency ranges. In many contexts, a second problem is simply the cost of the VCXO. This relates in part to the fact that the crystal cannot be integrated on the chip.

Other circuit designs involve a crystal directly as a reference clock. A crystal can only be used when the crystal acts as a reference for the whole system. The problem with this solution is that it is expensive and it might not be possible to use the crystal as a reference for the entire system.

The above-mentioned circuits and corresponding methods are based on the fact that the different parts of a digital circuit have to be somehow synchronised to a reference clock. Until now it has been commonly taught within the art that such reference clocks have to provide an accurate frequency clock signal.

### SUMMARY OF THE INVENTION

According to the invention, the above-mentioned problems or disadvantages are overcome by providing an integrated circuit comprising a pulse-width-modulator for converting a signal (input signal) into a pulse-width-modulated signal (output signal), the pulse-width-modulator being clocked by a clock signal generated by a clock generator, wherein the clock signal is a free-running clock signal. Specifically said signal (input signal) could be a digital signal and said pulse-width-modulator could be a digital pulse-width-modulator.

In digital circuits, a clock is always used and the clock can either be an internal clock or an external clock (such as a crystal, etc). In connection with digital audio circuits, a precise and absolute frequency is typically needed. This absolute clock frequency is determined either by means of a crystal or a PLL that locks to an external signal.

According to the invention there is provided a unit comprising a clock oscillator integrated in the same unit as the PWM modulator and SRC. According to the invention there is thus provided a totally integrated solution, for instance implemented as a chip. According to the invention, the external crystal or the use of a PLL with an external reference is thus avoided, which among others yields a less expensive and more efficient system.

By providing a free-running clock signal it is advantageously achieved that the complexity of the clock generator may be reduced. Thus, tolerances of components for providing the free-running clock signal do not necessarily have to be as narrow as usual and thereby less expensive components may be used in the integrated circuit.

It should be understood that the term ‘free-running clock’ is commonly known within the art and is often understood as being a clock extracted from a self-oscillating circuit or a stable multivibrator.

The term ‘free-running’ is related to the fact that the circuit is oscillating by the frequency determined by the specific choice of components in the design and is not forced or controlled to oscillate by any other frequency than the default. The tolerances of the components therefore determine the frequency at which the oscillator is oscillating.

When using an integrated digital PWM modulator, the need for a reference clock providing an accurate frequency clock signal is removed. Thus, any free-running clock signal is very suitable for this purpose.

In an advantageous embodiment, the clock generator may be an internal clock generator.

By providing an internal clock generator it is advantageously achieved that the use of external connections is reduced. Furthermore, the implementation of the circuit is simplified. Also the quality of the clock signal is determined by the design process, and the quality of the whole modulation system is thereby ascertained.

In an advantageous embodiment, the pulse modulator can be a self-oscillation modulator, such as the “Dcom” modulator produced by the applicant. This provides an integrated circuit which does not need a phase margin and which will have a higher loop gain to suppress error and noise components.

In an advantageous embodiment, the clock generator may be a ring oscillator. By providing a ring oscillator it is advantageously achieved that the complexity is highly reduced compared to other oscillators. The technology of the ring oscillator is well known, and a low noise oscillator is fairly easily created. It is well known that the ring oscillator provides a low precision of the frequency; however, the integrated circuit according to the invention advantageously allows the use of such clock generators.

Furthermore, since the pulse-width-modulator does not have a need for an exact relationship between the sample rate of the data and the clock signal generated by the oscillator, the digital signal may advantageously not be synchronous with the oscillator. Thus, it is achieved that any sample rate on the digital signal may be accepted.

In an advantageous embodiment, the clock generator is initially tuned to a predetermined frequency. By initial tuning of the oscillator it is advantageously achieved that the frequency of the free-running oscillator is kept within limits typically set by EMI requirement.

The present invention relates furthermore to a method of clock-controlling a pulse-width modulator for converting a signal into a pulse-width-modulated signal, according to which method the pulse-width modulator is clock-controlled by a free-running clock signal. Preferably said signal is a digital signal and said pulse-width modulator is a digital pulse-width modulator.

The present invention furthermore relates generally to the use of a free-running clock signal for clock-controlling pulse-width modulators and specifically for controlling digital pulse-width modulators.

### BRIEF DESCRIPTION OF THE DRAWING

The present invention will be better understood with reference to FIG. 1 in conjunction with the following detailed description of a presently preferred embodiment of the invention.

FIG. 1 shows a schematic block diagram of a typical embodiment of the invention.

### DETAILED DESCRIPTION OF THE INVENTION

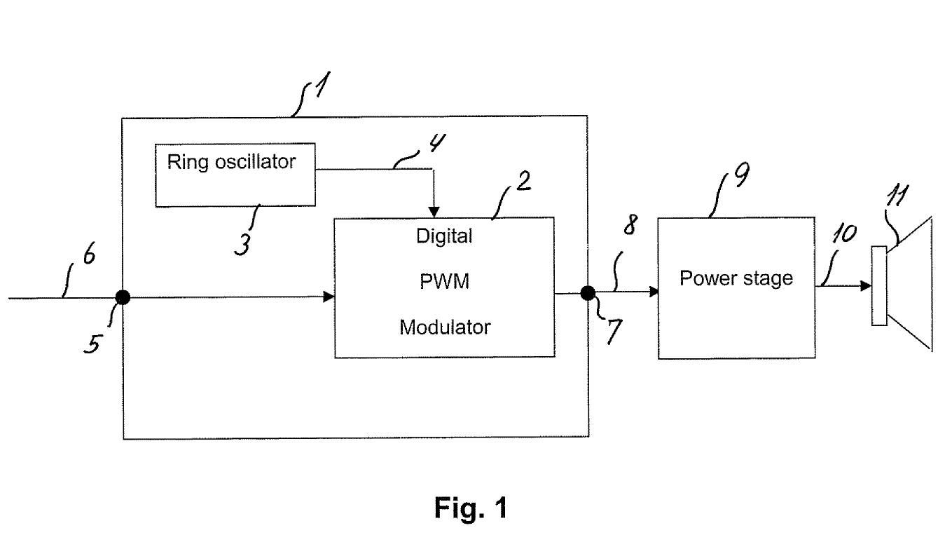

With reference to FIG. 1 there is shown a specific embodiment of the invention comprising an integrated circuit 1 provided with a digital pulse-width-modulator 2, which converts a multi bit digital audio input signal 6 provided on an input terminal 5 into a single bit PWM signal 8 provided on an output terminal 7. The signal 8 is in this embodiment provided to an analogue output stage 9 that provides the PWM signal 10 to the transducer 11, which may be a loudspeaker, as shown in FIG. 1. It is understood that the output signal 8 provided by the PWM modulator 2 may be utilised in other ways and that conversion to an audible signal, for instance emitted by a loudspeaker may be carried out by other means.

The digital pulse-width-modulator 2 is clocked by a fast system clock signal 4 in order to make the required calculations in the various digital processing means of the system. According to this embodiment of the invention, the system clock signal 4 is generated by a free-running ring oscillator 3, but it is as mentioned previously understood that other types of free-running oscillators may alternatively be used.

1. An integrated circuit comprising a pulse-width-modulator (2) for converting an input signal (6) into a pulse-width-modulated signal (8), the pulse-width modulator (2) being clocked by a clock signal (4) generated by a clock generator (3) generating a free-running clock signal.

2. An integrated circuit according to claim 1, where said input signal (6) is a digital signal.

3. An integrated circuit according to claim 1 or 2, where the clock generator (3) is provided in the same integrated circuit (1) as the pulse-width modulator (2).

4. An integrated circuit according to any of the preceding claims 1 to 3, wherein said pulse-width modulator (2) is a digital pulse-width modulator.

5. An integrated circuit according to any of the preceding claims, wherein the pulse-width modulator (2) is a self-oscillation modulator.

6. An integrated circuit according to any of the preceding claims, wherein the clock generator (3) is a ring oscillator.

7. An integrated circuit according to any of the preceding claims, wherein the clock signal (4) is asynchronous relative to the digital data stream of the input signal (6).

8. An integrated circuit according to any of the preceding claims, wherein the clock generator (3) is initially tuned to a predetermined frequency.

9. Method of clock-controlling a pulse-width modulator (2) for converting an input signal (6) into a pulse-width-modulated signal (8), according to which method the digital pulse-width modulator (2) is clock-controlled by a free-running clock signal (4).

10. A method according to claim 9, wherein said pulse-width modulator (2) is a digital pulse-width modulator.

11. A method according to claim 9 or 10, wherein said input signal (6) is a digital signal.

12. Method according to claim 9, 10 or 11, where said free-running clock signal (4) is provided by a free-running oscillator (3).

13. Method according to any of the preceding claims 9 to 12, where the free-running oscillator (3) is provided in the same integrated circuit (1) as the digital pulse-width modulator (2).

14. Method according to any of the preceding claims 9 to 13, where the frequency of the free-running clock signal (4) is initially tuned to a predetermined frequency.

15. Method according to any of the preceding claims 9 to 14, where said free-running oscillator (3) is a ring oscillator.

16. The use of a free running clock signal for controlling a pulse-width modulator.

17. The use according to claim 16, where said pulse-width modulator is a digital pulse-width-modulator.
